(19) United States
(12) Patent Application Publication
(10) Pub. No.: US 2025/0037908 A1
(43) Pub. Date: Jan. 30, 2025

(54) ELECTRICAL ISOLATOR

(71) Applicant: EB REBOSIO S.R.L., Montichiari (Brescia) (IT)

(72) Inventor: Alberto SCARPETTA, Montichiari (Brescia) (IT)

(21) Appl. No.: 18/836,852

(22) PCT Filed: Feb. 9, 2023
(86) PCT No.: PCT/IB2023/051175

§ 371 Date: Aug. 8, 2024

(30) Foreign Application Priority Data
Feb. 9, 2022 (IT) 102022000002357

(51) Int. Cl. H01B 17/00; G01R 31/12; G01R 31/52; H02J 7/00; H02J 7/34

(52) U.S. Cl. CPC H01B 17/005; G01R 31/1245; G01R 31/52; H02J 7/0068; H02J 7/34; H02J 2207/50

(57) ABSTRACT

An electrical isolator having an isolator body and at least one leakage current measurement sensor embedded in the isolator body and configured to measure the leakage currents circulating on a surface of the isolator body is provided. The leakage current measurement sensor is self-powerable by electric energy produced by the leakage currents. The electrical isolator is for high-voltage lines.

### CROSS-REFERENCE TO RELATED APPLICATIONS

This application is a National Phase Application of PCT International Application PCT/IB2023/051175, having an International Filing Date of Feb. 9, 2023 which claims priority to Italian Application No. 102022000002357 filed Feb. 9, 2022, each of which is hereby incorporated by reference in its entirety.

### TECHNICAL FIELD

The present disclosure relates to an electrical isolator, in particular for high-voltage lines.

### BACKGROUND

As is known, in overhead electrical power transmission or distribution lines, electrical conductors are carried by lattice or pylon structures, each of which comprises one or more electrical isolators that support one or more electrical conductors by isolating them with respect to the ground.

Typically, isolators are made of glass or porcelain, but recently isolators made of polymeric materials, e.g., silicone, are spreading, and are particularly valued for their light weight and electrical performance.

As is known, the body of these electrical isolators has one or more disks coaxial to the main axis of the isolator, which increase its isolating surface, i.e., the leakage path.

All electrical isolators, regardless of their construction, are still run through, along their outer surface, leakage currents to ground. These leakage currents are only a few microamperes when the isolator is new. However, the leakage currents may increase over time to the point where the isolator becomes unusable.

In the case of glass and porcelain isolators, high leakage currents may cause the disks to burst. The isolator must then be replaced.

In the case of isolators made of polymeric materials, on the other hand, the degradation caused by leakage currents increases imperceptibly from the outside, as there is no bursting of the disks. There may therefore be damaged or highly degraded isolators, but their identification is not immediate and requires periodic testing of all the isolators in a line.

There is therefore a great need to keep the leakage currents of the isolators monitored so as to detect an abnormal increase in these currents before complete failure of the isolator occurs and therefore when it is still possible to intervene on only the degraded isolator with a maintenance intervention, for example washing the isolator.

Leakage current monitoring devices that may be installed on an isolator have already been proposed; however, such devices must be powered electrically and are very bulky and therefore expensive. As they have to be installed on each isolator, their use has been very low.

### SUMMARY

The object of the present disclosure is to propose an electrical isolator, in particular for high-voltage lines, which is capable of providing monitoring of surface leakage currents but which is free from the limitations suffered by isolators with known monitoring devices.

This is achieved with an electrical isolator and a leakage current monitoring method as described and claimed herein.

Preferred or advantageous embodiments of the electrical isolator according to the present disclosure are also described.

According to one general embodiment, the electrical isolator according to the present disclosure, particularly suitable for use on a high-voltage line, comprises:
an isolator body mainly extending along an isolator axis between a first end, suitable for being electrically connected to an electrical conductor of an electrical line, and a second end, suitable for being electrically connected to ground, and
at least one leakage current measurement sensor at least partially embedded in the isolator body and configured to measure the leakage currents circulating on the surface of the isolator body.

According to one aspect of the disclosure, the sensor is self-powerable by means of the electric energy produced by the leakage currents themselves.

More specifically, the sensor is equipped with storage means for storing the electric energy generated by the leakage currents.

In a preferred embodiment, the sensor comprises data transmission means suitable for transmitting the measured values of the leakage currents.

For example, the data transmission means comprise wireless communication means, for example obtained by a “Long Range Radio” (“LoRa”) system.

Thus, the concept behind the present disclosure is to provide an electrical isolator that is able to monitor and communicate its operating status without an external power supply.

The electrical isolate takes advantage of the fact that the materials of which it is made, while they are by their nature insulating, nevertheless allow, when subjected to high voltage, even when new, for surface leakage currents of micro/milliamperes to flow to ground.

The sensor is thus configured to “capture” these surface currents so that it has sufficient energy to run the low-power electronic circuits needed for measurement and external communication of the leakage current values.

In one embodiment, the sensor comprises a flexible electronic board that forms an annular band positioned coaxially to the axis of the isolator or extending along a cylindrical lateral portion of the isolator body, mainly in the direction parallel to the isolator axis.

In one embodiment, for example wherein the flexible electronic board forms an annular band, at least two electrodes suitable for capturing the surface leakage currents are mounted on the flexible electronic board in at least two axially distinct points on the outer surface of the isolator body, in such a way as to detect a voltage difference proportional to the intensity of the leakage current.

In a variant embodiment, the sensor comprises two annular-shaped electrodes, e.g., two windings acting as antennas, placed around the isolator body and spaced apart axially, each connected electrically to a respective end of the flexible electronic board, which is embedded in the isolator body between the two annular-shaped electrodes.

In a preferred embodiment, the isolator body comprises a load-bearing structure, for example made of fiberglass, and an outer covering made of a polymeric material, such as silicone, which at least partially covers the load-bearing structure.

The sensor is placed under such an outer covering and/or is embedded in the outer covering, possibly with the exception of the annular conductor elements described above, which are wound over the outer covering.

In the case of an annular electronic board bearing the electrodes, these electrodes extend radially from the electronic board so as to graze the outer surface of the outer covering.

In a preferred embodiment, the sensor further comprises a backup battery suitable for powering the sensor in the absence of electric energy on the electrical conductor.

Therefore, the sensor allows for its operation even when the line is not powered, for example immediately after installation or during line interruptions, by means of a power backup, such as with a lithium button battery. In this way, alarm signals may be sent.

For example, the backup battery may be sized to have a 30-year lifetime with one emergency transmission per day.

If, on the other hand, the line is powered, the power is provided by the surface leakage current.

In one embodiment, the sensor may be activated, for example at the time of installation, by a short-range wireless communication system, for example based on RFID technology.

Upon activation of the line, the power for monitoring and transmission is drawn from the surface leakage currents. Power from the storage battery is thus reserved for emergency situations with a line that is not powered.

After activation, the sensor may monitor and transmit the leakage currents continuously or at configurable time intervals.

The disclosure also relates to a method for measuring the surface leakage currents in an electrical isolator, in particular for high-voltage lines, which in one embodiment comprises the steps of:
embedding a leakage current measurement sensor at least partially in the isolator body, the sensor being configured to measure the leakage currents circulating on the surface of the isolator body;
electrically powering the sensor with the electric energy produced by the leakage currents themselves.

According to one aspect of the disclosure, the method involves transmitting the measured leakage current values to a remote receiving unit.

### BRIEF DESCRIPTION OF THE DRAWINGS

Further features and the advantages of the electrical isolator according to the disclosure shall be made readily apparent from the following description of preferred exemplary embodiments thereof, provided purely by way of a non-limiting examples, with reference to the accompanying figures, wherein:

FIG. 1 schematically illustrates an example of an electrical isolator according to the disclosure;

FIG. 2 is a perspective view of a portion of an electrical isolator according to the disclosure, in a variant embodiment;

FIG. 2a is a perspective view of the isolator portion of FIG. 2, wherein the insulating covering has been removed so as to show the configuration of the leakage current measurement sensor;

FIG. 3 is a block diagram of the leakage current measurement sensor of the electrical isolator, in one embodiment;

FIG. 4 is a block diagram of the leakage current measurement sensor of the electrical isolator, in a variant embodiment;

FIG. 5 is a simplified representation of a flexible electronic board of the leakage current measurement sensor, in one embodiment, before it is wrapped around the isolator body; and

FIG. 6 is a schematic representation of an overhead electrical line, the electrical isolators of which according to the disclosure communicate data to a gateway, which is connected to a remote server.

### DETAILED DESCRIPTION OF THE DRAWINGS

In the following description, elements common to the different isolator embodiments are given the same reference numbers.

In the attached drawings, an electrical isolator according to the disclosure has been denoted as a whole with 1; 1000. For example, the electrical isolator is suitable for operating on 50 Hz and 60 Hz high-voltage electrical lines.

The electrical isolator 1; 1000 comprises an isolator body 10 extending mainly along an isolator axis X between a first end 10a, suitable for being electrically connected to an electrical conductor 2 of an overhead electrical line 4, and a second end 10b, suitable for being electrically connected to ground.

The electrical isolator 1 is equipped with at least one sensor 12; 120 for measuring leakage currents, or surface currents, at least partially embedded in the isolator body 10 and configured to measure leakage currents circulating on the surface of the isolator body.

In one embodiment, the isolator body comprises a load-bearing structure 101, for example made of fiberglass, and an outer covering 102 made of polymeric material, e.g., silicone, which at least partially covers the load-bearing structure 101.

The sensor 12; 120 comprises at least one electrode 16; 160 suitable for capturing the surface leakage currents flowing along the outer covering 102 and an electronic board 14; 140 connected to the at least one electrode 16; 160 and comprising all the electronic circuits and components necessary for processing the electrical signals detected by means of the at least one electrode and possibly received from other sensors, transmitting data to an external receiving unit, and storing the electric energy required to self-power the sensor, as will be further described below.

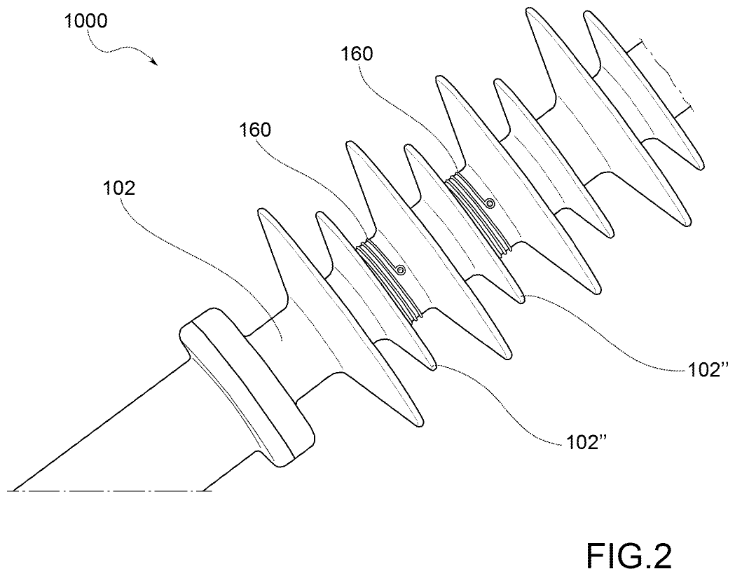

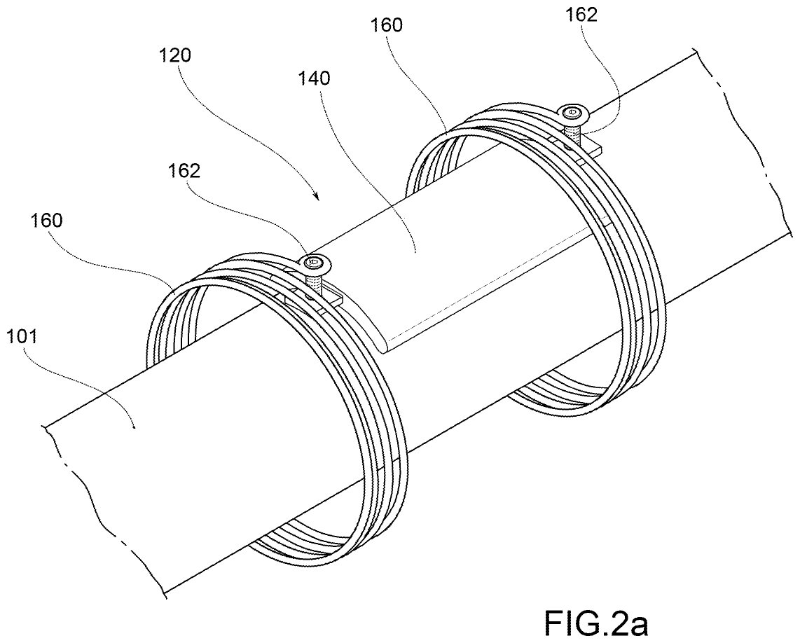

To collect the leakage currents, the at least one electrode 16; 160 offers to the leakage current an input impedance (e.g., equal to 50 kOhm) much less than that of the surface circuit offered by the isolator-air layer in the isolator sector concerned by the at least one electrode 16; 160 or between two electrodes 160 (FIG. 2, 2a).

The electrodes 16; 160 may be made in various shapes and materials and may have an upper limit of resistivity, for example an order of magnitude lower than that of the material used as an isolator, which for silicone and fiberglass is between 10¹² and 10¹⁴ Ωm, and as a lower limit of resistivity, the resistivity of conducting metals.

These values provide a lower impedance path for the leakage current in the input circuit of the sensor.

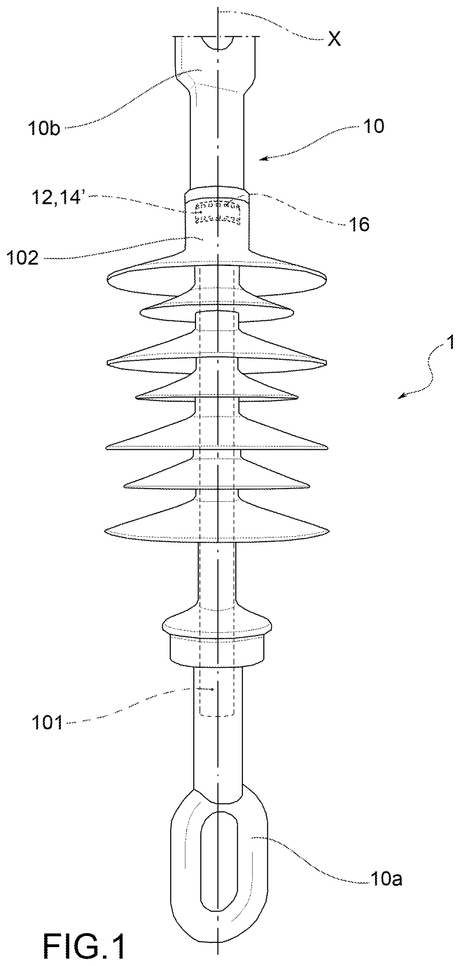

In an embodiment shown in FIG. 1, the sensor 12 is positioned under the outer covering and/or is embedded in the outer covering. The sensor 12 is thus completely protected from the elements and dirt.

In one embodiment, the at least one electrode 16; 160 has an annular shape and is arranged coaxially to the isolator axis X.

In one embodiment, the sensor 12; 120 comprises two annular-shaped electrodes 16; 160 spaced axially along the isolator axis X so as to detect a voltage difference proportional to the intensity of the leakage current.

In an embodiment shown in FIG. 1, the sensor 12 comprises a flexible electronic board 14 that forms an annular band 14′ positioned coaxially to the axis X of the isolator. The annular band 14′ has a lower input impedance than that of the material of the outer covering 102.

At least two parallel rows of electrodes 16 suitable for capturing the surface leakage currents in at least two axially distinct points are mounted on the flexible electronic board 14 so as to detect a voltage difference proportional to the intensity of the leakage current.

For example, the electrodes 16 extend radially from the flexible electronic board 14 so as to graze the outer surface of the isolator. The electrodes 16 of the same row may be electrically connected together to form a single annular-shaped electrode, for example by means of a conductive paint.

The flexible electronic board 14 supports all the electronic circuits and components necessary for processing the electrical signals detected by means of the electrodes, transmitting data to an external receiving unit, and storing the electric energy needed to self-power the sensor, as will be described below.

In a variant embodiment illustrated in FIGS. 2 and 2a, the sensor 120 comprises at least one pair of electrodes 160 arranged on the surface of the isolator body 10 and spaced axially apart from each other. Each electrode 160 forms a coiled winding on the outer covering, coaxially to the isolator axis, so as to form an antenna. For example, each electrode 160 is obtained with a winding of a conductive wire, for example made of stainless steel or semiconductive silicone.

These antennas are capable of capturing both the surface electrical charges and the electrical field in the air. One terminal of each electrode 160 is electrically connected, for example by a screw 162, to an electronic board 140 embedded in, or placed under, the outer covering. As mentioned above, the electronic board 140 comprises all the electronic circuits and components necessary for processing the electrical signals detected by means of the electrodes 160 and possibly provided by other sensors, as further described below, for data transmission to an external receiving unit, and for storing the electric energy required to self-power the sensor, as will be described below.

In this embodiment, the electronic board 140, which may be made of a flexible material to fit the curvature of the cylindrical surface of the isolator body 10, extends mainly parallel to the isolator axis X.

In one embodiment, the two electrodes 16; 160 are devoid of a fixed ground connection. In this way, the sensor 12; 120 remains fluctuating, and therefore, if there are surges, the sensor is not subjected to a major potential difference and is therefore not damaged.

In an embodiment illustrated in FIG. 2, the electrodes 160 are placed under various isolator disks 102′, 102″ so that each is protected from atmospheric agents. To better collect the leakage currents, the two electrodes 160 are spaced axially so that two or more isolator disks are interposed between them, as shown in FIGS. 2 and 2a.

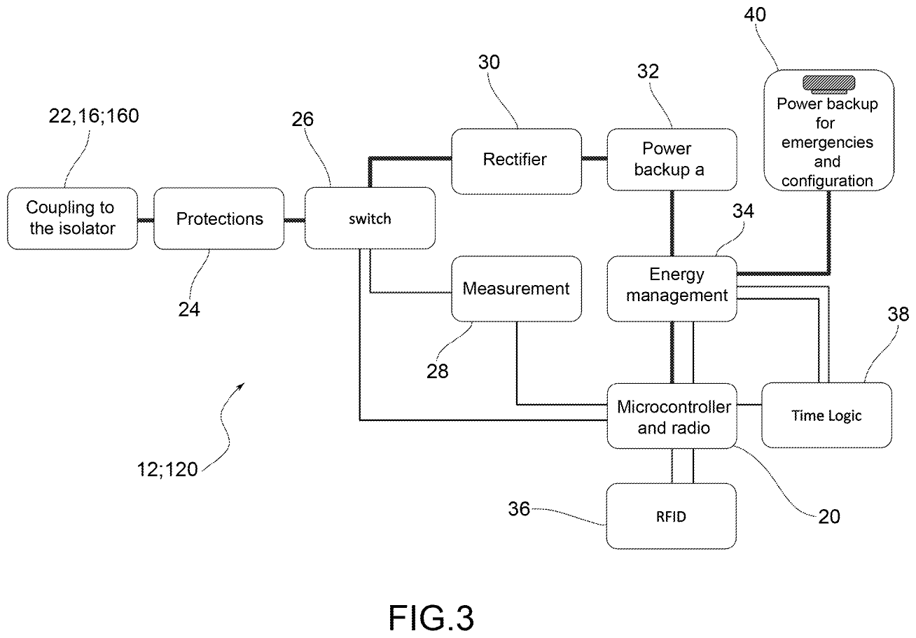

FIG. 3 is a block diagram of the functional elements of the sensor 12; 120, according to a possible embodiment.

The core of the sensor 12; 120 is a microcontroller 20 that manages the operation of the sensor and the communication of the data to the outside.

In one embodiment, the sensor 12; 120 may be provided with electrical and mechanical coupling means 22 for the to the isolator body 10.

For example, these coupling means 22 comprise the electrodes 16 that also perform, in addition to the function of capturing the surface leakage currents, a mechanical function of locking the sensor 12 in place, as these electrodes 16 are embedded in the outer covering made of polymeric material.

The sensor 12; 120 may be equipped with electronic protection means 24 suitable for protecting the sensor from voltage/current spikes, for example generated by lightning.

The leakage current captured by the electrodes 16 is managed by a switch 26, which, in a manner controlled by the microcontroller 20, diverts the current alternately to an electronic current-measuring module 28 or to energy storage means 32, for example obtained by means of one or more capacitors. A rectifier circuit 30 may be provided upstream of the switch 26 or at the input of the energy storage means 32.

The energy storage means 32 are controlled by an energy management module 34, which in turn is operatively connected to the microcontroller 20.

The microcontroller 20 is configured to manage an RFID transponder 36 and a timing logic 38.

The RFID transponder 36 may be used to identify the electrical isolator 1 and/or the sensor 12; 120 and may be read/write-enabled to change the initialization parameters of the sensor 12; 120. If provided with a battery, the RFID transponder may also be used to enable/configure the monitoring functions of the sensor 12; 120, for example at the time of installation. This makes it possible, for example, to detect and transmit the geolocation of the isolator.

The sensor 12; 120 may also comprise a backup battery 40 that is operatively connected to the energy management module 34.

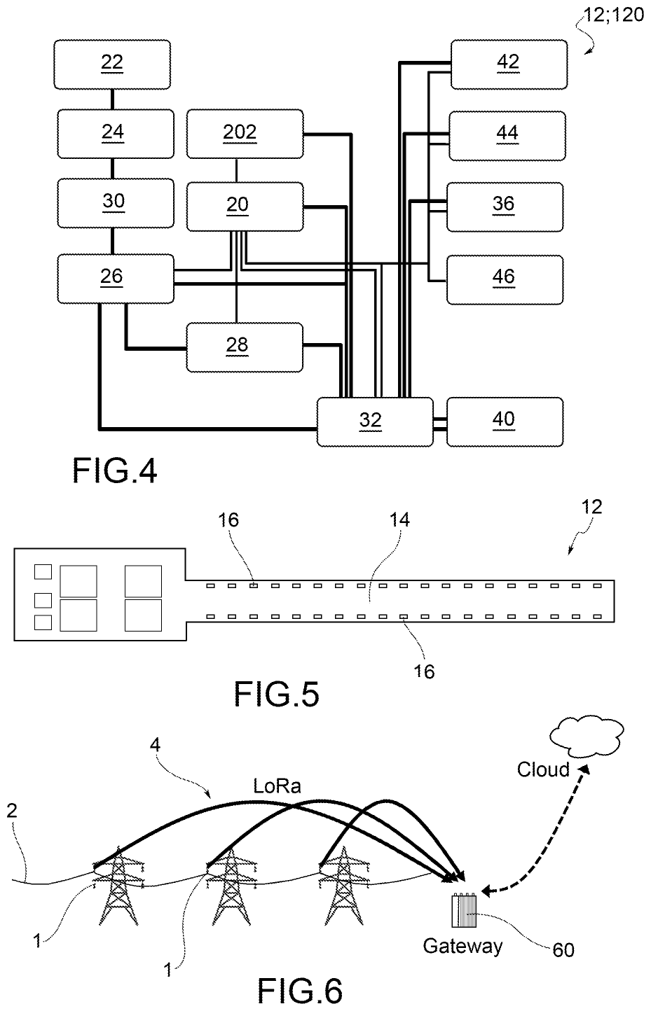

Some of the functional components of the sensor 12 will now be described in more detail, according to an on the embodiment illustrated in the block diagram in FIG. 4, wherein the elements common to or equivalent to those shown in FIG. 3 are indicated by the same reference numbers.

During normal operation of the isolator, the leakage currents flow over the surface of the outer covering 102.

The leakage currents are measured by the electronic current measurement module 28. The sampling profile, the detection times and the accuracy may be customized according to the energy storage capacity. For example, the time interval between one measurement and the next may be about 1 minute. The sampling frequency and data transmission frequency may be adjustable, for example by the RFID transponder or by the “LoRa” module.

In some embodiments, two measurement options may be provided:
average current, which is the average leakage current flowing through the isolator during the sampling period;
instantaneous current, which is the current intensity at the time of sampling.

As mentioned above, the microcontroller 20 manages the data transmission to an external receiving unit, for example a gateway 60 (FIG. 6), which in turn is connected to the Cloud.

In one embodiment, the data transmission is implemented by a communication module 202, managed by the microcontroller 20, for example based on a “LoRa” communication protocol, which allows transmission with low power consumption up to a distance of a 2-5 km radius depending on the environmental and topographical conditions of the installation area of the isolator.

The electronic protection means 24 are configured to protect the sensor from major electrical events, for example lightning, which may overcome the resilience of the isolator and sensor and of the IMU to high mechanical stress and overheating situations, causing damage to the isolator and/or the sensor.

In some embodiments shown in the block diagram in FIG. 4, the electrical isolator 1 is equipped with additional sensors. These additional sensors may be supported by the same flexible electronic board 14; 140 and/or may be controlled by the same microcontroller 20 that manages the monitoring of the leakage current. Moreover, the additional sensors may also be operatively connected to the energy management module 34.

These additional sensors may include a temperature sensor 42. The temperature of the isolator may be used as an aging parameter and/or to detect critical situations. Since the leakage current measurement sensor 12 does not generate appreciable heat, the measured temperature is closely related to the temperature of the isolator in the vicinity of the leakage current measurement sensor.

The additional sensors may include a position sensor 44. The position (especially the tilt angles) of the isolator may be an indication of mechanical anomalies. This position sensor 44 may also be managed by the electronics of the leakage current measurement sensor 12.

The additional sensors may include a strain gauge 46 to monitor possible mechanical stresses on the isolator. This strain gauge 46 may also be managed by the electronics of the leakage current measurement sensor 12.

The sensor 12; 120 described above is capable of intercepting very low surface currents, for example 5-10 microamperes, due to its conducting elements.

As explained above, these surface currents pass into an input circuit of the microprocessor electronic circuit. The input circuit is configured to rectify the sinusoidal shape of the leakage current, for example by means of a rectifier bridge with appropriate commercial electronic circuitry, so as to obtain a direct current used to progressively charge an energy storage capacitor battery, for example having a capacity of 1.2 microfarad.

This energy accumulates progressively until it reaches a threshold that the microprocessor deems sufficient to allow the sensor to process and transmit, for example by sending a LORA message, the information received from the various sensors (for example temperature information, mechanical load of the isolator, orientation of the isolator, charge time of the capacitor, and/or other information deemed useful).

In one embodiment, if the stored energy is more than is needed to make such periodic transmissions, for example twice a day, the excess energy is stored in a backup battery. In case of an unpowered line, the backup battery may allow the sensor to continue transmitting information for a certain period of time.

It should be noted that, since the available currents may be of the order of microamperes, the electronics of the sensor are sized to operate with energies of the order of millijoules. A reference value for industrially producible objects may be 3 mJ for the energy required for the sensor to perform operations related to a work session, such as for example: powering on, charging, processing, communication, and powering off.

As mentioned above, the surface current, flowing inside the sensor, charges the capacitor battery. In one embodiment, the charging circuit of the capacitor, upon reaching the minimum energy required for the sensor to self-power, sends a signal to the microcontroller and wakes it up. The microcontroller may then perform the operations of monitoring the signals coming from the sensors, for example from the accelerometer and temperature sensor, prepares a message containing the information on the state of the isolator, and sends it, for example, via LoRa radio built into the sensor.

For example, a 22 microfarad (μF) capacitance charged to 18V may be used for an energy of 3 mJ.

Field and laboratory tests confirm that, relative to the surface leakage current, the line-isolator-ground circuit acts mainly as a current generator, and thus charges the self-powering capacitors with constant current. Therefore, the charging time is proportional to the leakage current. With this assumption, the time between two consecutive transmissions is a valid measure of the amount of total electrical charge circulating between the two transmissions. In this case, the receiving gateway processes relevant times and current values.

In cases where the sensor is provided with a rechargeable battery, for example to use the sensor even in situations where there is a power failure on the line, a device, such as a Real Time Clock (RTC) may enable the sensor to estimate the elapsed time between the two transmissions and autonomously provide leakage current values.

From the above description, it is evident how the proposed electrical isolator enables the technical problem underlying the disclosure to be solved.

The leakage current measurement sensor is self-powered by the leakage currents themselves and therefore does not require a connection to an electrical line or the use of bulky batteries, which are prone to discharge, or photovoltaic panels.

Thus, the sensor is particularly miniaturized and does not affect the footprint of the isolator. The sensor is fully protected by being embedded in the outer covering or, in the case of electrodes wrapped on the outer covering, they are placed underneath, and thus protected by, the isolator disks.

The cost of the sensor does not significantly affect the total cost of the isolator, and therefore all isolators may be equipped with the sensor.

The sensor enables constant and accurate monitoring of leakage currents and thus of the performance degradation of the isolator and allows for monitoring of the maintenance state of the line.

For example, if an entire batch of isolators is found to have higher than normal leakage currents, it may be that the entire line needs to be washed with pressure washers to remove surface deposits that cause micro-discharges. Currently, electrical isolators are washed a couple of times a year. With the isolator according to the disclosure, it is possible to know precisely when the washing should be done. It may turn out, for example, that washing is not needed or instead that a line needs to be washed several times a year or there is only one section of line to be washed and not the whole line.

The maintenance of a line is thus greatly streamlined.

In order to meet contingent needs, a person skilled in the art may make a number of changes, adaptations, and substitutions of elements with other functionally equivalent ones to the embodiments of the electrical isolator according to the disclosure, without departing from the scope of the following claims. Each of the features described as belonging to a possible embodiment may be obtained independently of the other described embodiments.

1-21. (canceled)

22. An electrical isolator, comprising:
an isolator body mainly extending along an isolator axis between a first end, suitable for being electrically connected to an electrical conductor of an electrical line, and a second end, suitable for being electrically connected to ground, the isolator body comprising a load-bearing structure and an outer covering made of polymeric material which at least partially covers the load-bearing structure, and
at least one leakage current measurement sensor at least partially embedded in the isolator body and configured to measure leakage currents circulating on a surface of the isolator body, wherein the leakage current measurement sensor is self-powerable by electric energy produced by the leakage currents,
wherein the leakage current measurement sensor comprises:
at least one electrode suitable for capturing the leakage currents flowing along the outer covering and an electronic board connected to the at least one electrode, the leakage current measurement sensor being embedded in the isolator body, or
two annular-shaped electrodes suitable for capturing the leakage currents flowing along the outer covering and placed around the isolator body and spaced axially apart, each annular-shaped electrode being electrically connected to a respective end of an electronic board, the electronic board being embedded in the isolator body between the two annular-shaped electrodes,
wherein the electronic board comprises all electronic circuits and components necessary for processing electrical signals detected by the at least one electrode, transmitting data to an external receiving unit, and storing the electric energy required to self-power the leakage current measurement sensor,
wherein the electronic circuits and components comprise a microcontroller configured to manage electronics for detecting and measuring the leakage currents, electric energy storage, and communication of data towards outside and/or other sensors,
and wherein the electronic circuits and components further comprise an input circuit configured to rectify a sinusoidal shape of the leakage currents so as to obtain a direct current used to progressively charge an energy storage capacitor battery, wherein the input circuit is operatively connected to a capacitor battery charging circuit which, upon reaching a minimum energy required for the leakage current measurement sensor to self-power, is configured to send an activation signal to the microcontroller.

23. The electrical isolator of claim 22, wherein the electrical isolator is for high-voltage lines.

24. The electrical isolator of claim 22, wherein the electronic circuits and components necessary for transmitting data comprise wireless communication means.

25. The electrical isolator of claim 24, wherein the wireless communication means are based on a long range (LoRa) radio system and/or a radio-frequency identification (RFID) system.

26. The electrical isolator of claim 22, wherein each electrode of the two annular-shaped electrodes forms a coiled winding on the isolator body so as to form an antenna.

27. The electrical isolator of claim 22, wherein the leakage current measurement sensor further comprises a flexible electronic board which forms an annular band positioned coaxially to the isolator axis.

28. The electrical isolator of claim 27, wherein at least two electrodes, suitable for capturing the leakage currents in two axially distinct points of an outer surface of the isolator body are mounted on the flexible electronic board.

29. The electrical isolator of claim 22, wherein the leakage current measurement sensor further comprises a backup battery suitable for powering the leakage current measurement sensor in absence of the electric energy on the electrical conductor.

30. The electrical isolator of claim 22, further comprising a switch controlled by the microcontroller to divert the leakage currents captured alternatively to an electronic current measurement module or to the input circuit which powers energy storage means.

31. The electrical isolator of claim 22, wherein the leakage current measurement sensor comprises a radio-frequency identification (RFID) transponder queryable to identify and/or geolocate and/or activate the electrical isolator and/or the leakage current measurement sensor.

32. The electrical isolator of claim 22, further comprising at least one further sensor selected from a temperature sensor, a position sensor, or a strain gauge, said at least one further sensor being operatively connected to the microcontroller.

33. A method for measuring surface leakage currents in an electrical isolator, wherein the electrical isolator comprises an isolator body mainly extending along an isolator axis between a first end, suitable for being electrically connected to an electrical conductor of an electrical line, and a second end, suitable for being electrically connected to ground, the isolator body comprising a load-bearing structure and an outer covering made of polymeric material which at least partially covers the load-bearing structure, the method comprising:
at least partially embedding at least one leakage current measurement sensor in the isolator body, the leakage current measurement sensor being configured to measure leakage currents circulating on a surface of the isolator body,
electrically powering the leakage current measurement sensor with electric energy produced by the leakage currents,
wherein the leakage current measurement sensor comprises:
at least one electrode suitable for capturing the leakage currents flowing along the outer covering and an electronic board connected to the at least one electrode, the leakage current measurement sensor being embedded in the isolator body, or
two annular-shaped electrodes suitable for capturing the leakage currents flowing along the outer covering and placed around the isolator body and spaced axially apart, each annular-shaped electrode being electrically connected to a respective end of an electronic board, the electronic board being embedded in the isolator body between the two annular-shaped electrodes,
wherein the electronic board comprises all electronic circuits and components necessary for processing electrical signals detected by the at least one electrode, transmitting data to an external receiving unit, and storing the electric energy required to self-power the leakage current measurement sensor,
wherein the electronic circuits and components comprise a microcontroller configured to manage electronics for detecting and measuring the leakage currents, electric energy storage, and communication of data towards outside and/or other sensors,
and wherein electrically powering the leakage current measurement sensor with the electric energy produced by the leakage currents comprises:
rectifying a sinusoidal shape of the leakage currents input to the sensor to obtain a direct current;
progressively charging an energy storage capacitor battery with the direct current, and
upon reaching a minimum energy required for the leakage current measurement sensor to self-power, sending an activation signal to the microcontroller.

34. The method of claim 33, further comprising transmitting measured leakage current values to a remote receiving unit.

35. The method of claim 33, wherein, in absence of the electric energy on the electrical conductor, the leakage current measurement sensor is powered by a backup battery.

36. The method of claim 33, wherein the electrical isolator is for high-voltage lines.
